(19) United States
(12) Patent Application Publication
(10) Pub. No.: US 2024/0151773 A1
(43) Pub. Date: May 9, 2024

(54) Method of Building Battery SOH Estimation Model Based on Actual Vehicle Collection Big Data and Battery SOH Model Building System

(71) Applicants: Hyundai Motor Company, Seoul (KR); Kia Corporation, Seoul (KR)

(72) Inventors: Byung-Soo Park, Daejeon (KR); Hyun-Jun Jang, Daegu (KR); Woo-Sung Kim, Suwon-si (KR); Jae-Shin Yi, Seoul (KR)

(21) Appl. No.: 18/308,085

(22) Filed: Apr. 27, 2023

(30) Foreign Application Priority Data
Nov. 9, 2022 (KR) 10-2022-0148874

(51) Int. Cl. G01R 31/367; B60L 58/16; G01R 31/392

(52) U.S. Cl. CPC G01R 31/367; B60L 58/16; G01R 31/392

(57) ABSTRACT

An embodiment method of building a battery state of health (SOH) estimation model includes applying, by an optimization server, an error of a model voltage, an error of a measured voltage, a capacity, or a resistance of a battery mounted in a vehicle as an objective function and performing error minimization processing to derive optimal parameters of the battery.

### CROSS-REFERENCE TO RELATED APPLICATIONS

This application claims the benefit of Korean Patent Application No. 10-2022-0148874, filed on Nov. 9, 2022, which application is hereby incorporated herein by reference.

### TECHNICAL FIELD

Exemplary embodiments of the present disclosure relate to estimation of a state of health (SOH) of a battery.

### BACKGROUND

Recently, electric vehicles (xEV), which have increased in accordance with eco-friendly demands, mainly use battery packs as vehicle power sources. In this case, xEV refer to electric vehicles such as hybrid electric vehicles (HEV), plug-in hybrid electric vehicles (PHEV), and battery electronic vehicles (BEV).

Therefore, it is very important for the xEV to accurately estimate a state of health (SOH) of a battery. In this case, the SOH may be identified as a degree of aging (i.e., a degree of degradation) of the battery, and the degree of aging (i.e., the degree of degradation) of the battery can be known by a state change of current internal resistance and capacity according to vehicle traveling when compared to an ideal state (i.e., an initial state) of the battery.

As described above, the battery pack applied to the xEV is a power source which operates based on electrochemical characteristics and has a characteristic in which, as charging and discharging proceed, the electrochemical characteristics change due to an increase in internal resistance and a decrease in capacity.

For this reason, the xEV builds a battery SOH model on the basis of test data, applies the battery SOH model as a battery capacity model, and uses the battery capacity model in determining an SOH of the battery pack.

As an example, the test-based battery SOH model building logic establishes an electrochemical relational expression for deriving a capacity and internal resistance on the basis of a temperature, a state of charge (SOC), and a load, which are factors influencing the SOH of the battery, secures time-series data along with cell durability test data through a cell characteristics extraction test and a long-time cell durability test in various conditions of a temperature, an SOC, and a load, and builds an SOH model in which a model output value is a capacity using parameters of the electrochemical relational expression extracted on the basis of the cell durability test data.

In this way, the test-based battery SOH model is able to estimate a current SOH of the battery according to battery aging (degradation) in which a change of an internal parameter of the battery exhibits a nonlinear behavior, thereby increasing efficiency of battery control.

However, the test-based battery SOH estimation model is based on cell durability test battery data instead of actual vehicle driving/charging battery data so that advancement of a battery control algorithm is difficult.

As an example, in the test-based battery SOH model, the electrochemical relational expression uses only an average temperature, an average SOC, and an average load and does not entirely use time series data, and since all durability test values should be extracted in various conditions such as a temperature, an SOC, and a load, a test period is very long due to the nature of the durability test, and since a model output value of the SOH estimation model directly derives an SOH from a capacity, the SOH model itself is difficult to be used for other purposes so that extensibility is insufficient.

Therefore, it is difficult for the existing SOH estimation model to verify actual vehicle test data and the battery for each battery system assembly (BSA) unit, to reflect characteristics of individual vehicles to the SOH of the battery, and to consider driving profiles of all actual vehicles.

Most of all, the existing SOH estimation model can measure the internal resistance and capacity in a specific test condition to secure accuracy. However, it is practically impossible to periodically request performance of the corresponding test on vehicles sold to consumers.

### SUMMARY

Exemplary embodiments of the present disclosure relate to estimation of a state of health (SOH) of a battery. Particular embodiments relate to a battery SOH model building system in which an SOH estimation model is built through a Newman, Tiedmann, Gu, and Kim (NTGK) method, which uses a voltage as a model output value on the basis of big data collected from mass-produced vehicles and representing actual driving/charging of the battery so that chemical characteristics of a battery pack, which change according to a change of the SOH, can be accurately reflected.

An embodiment of the present disclosure provides a method of building a battery state of health (SOH) estimation model based on actual vehicle collection big data, in which a battery SOH estimation model of a voltage output value capable of indirectly identifying an SOH of a battery is built using an extraction parameter of actual vehicle driving/charging battery data with respect to the battery, which is collected from mass-produced vehicles and, particularly, a Newman, Tiedmann, Gu, and Kim (NTGK) voltage model applied to the battery SOH estimation model is optimized using big data according to accumulation of the actual vehicle driving/charging battery data and which is capable of estimating the SOH of the battery with high accuracy in real time in consideration of a driver's driving pattern, effectively classifying and learning accumulated actual driving history data according to operating conditions, and achieving advancement of a control algorithm reflecting chemical characteristics of a battery pack, which change according to a change in SOH condition, and a battery SOH model building system.

Other features and advantages of embodiments of the present disclosure can be understood by the following description and become apparent with reference to the exemplary embodiments of the present disclosure. Also, it is obvious to those skilled in the art to which the present disclosure pertains that the features and advantages of embodiments of the present disclosure can be realized by the means as claimed and combinations thereof.

In accordance with an embodiment of the present disclosure, there is provided a method of building a battery state of health (SOH) estimation model which includes establishing a battery Newman, Tiedmann, Gu, and Kim (NTGK) model in which the NTGK model is built from test data of a battery pack by an NTGK server and a model voltage is output to an optimization server from the NTGK model, extracting battery big data in which actual vehicle driving/charging battery data of a battery mounted in a vehicle is analyzed by a vehicle customer relation management (VCRM) server and a measured voltage is output to the optimization server, and optimizing a battery NTGK model in which an error between the model voltage and the measured voltage is set by the optimization server, the error is minimized by a gradient descent algorithm of machine learning for an objective function, and optimal parameters for a capacity and resistance of the battery are derived through error minimization.

As an exemplary embodiment, the establishing of the battery NTGK model may include collecting the test data in an initial capacity state in which the battery pack is not charged and discharged, extracting parameters related to a temperature and resistance from the test data as model fixed parameters, and performing NTGK processing on the model fixed parameters and building an NTGK model in which the model voltage is an output value.

As an exemplary embodiment, the test data may be a current, a voltage, and a temperature according to a temperature value and a current value.

As an exemplary embodiment, the extracting of the battery big data may include synthesizing, by the VCRM server, the actual vehicle driving/charging battery data of the battery transmitted from a VCRM terminal mounted in the vehicle, performing data pre-processing using the actual vehicle driving/charging battery data as big data through artificial intelligence, and extracting actual vehicle parameters having the measured voltage as an output value from the data pre-processing as a current, a temperature, and a voltage of the battery.

As an exemplary embodiment, the data pre-processing may apply a data unit which uses start-up on/off periods of the vehicle as one data set, may use a data set of a rest period after a start-up off period of a previous data set before a start-up on period, may use actual measurement information on a voltage, a current, and a temperature, may apply two or more of determined initial state of charge (SOC) values of the battery on the basis of the measured voltage value as a setting condition, and may analyze and classify the actual vehicle driving/charging battery data using the setting condition.

As an exemplary embodiment, the rest period is set to one hour after the start-off period.

As an exemplary embodiment, the optimizing of the battery NTGK model may include setting an initial condition for reducing the error, calculating an N^{th}-order objective function by applying the capacitance and the resistance as optimization variables elements and processing the objective function using the optimization elements by a gradient descent algorithm, confirming whether a tolerance value is satisfied, when the tolerance value is not satisfied, performing the calculating of the N^{th}-order objective function again and repeating the procedure and finding the optimal parameters for the optimization elements, and when the tolerance value is satisfied, deriving the optimization elements as the optimal parameters.

As an exemplary embodiment, the calculating of the N^{th}-order objective function may include setting a calculation result of the objective function as a first-order calculation value of the objective function, normalizing a slope of the objective function using the gradient descent algorithm, applying the slope of the objective function to the tolerance value and deriving a shift direction of the optimization elements, and setting the calculation result of the objective function as an N^{th}-order calculation value of the objective function in the shift direction of the optimization elements.

As an exemplary embodiment, the operation of the repeating of the procedure may include comparing the N^{th}-order calculation value of the objective function with the first-order calculation value of the objective function, when the N^{th}-order calculation value of the objective function is greater than the first-order calculation value of the objective function, reducing a step size for changing the tolerance value, and when the N^{th}-order calculation value of the objective function is smaller than the first-order calculation value of the objective function, increasing the number of repetitions of a total type step.

As an exemplary embodiment, the reducing of the step size may be set to ½ compared to a previous step, and after the reducing of the step size, the procedure may return to the deriving of the shift direction of the optimization elements during the calculating of the N^{th}-order objective function by applying the slope of the objective function to the tolerance value.

As an exemplary embodiment, the increasing of the number of repetitions may return to the normalizing of the slope of the objective function using the gradient descent algorithm during the calculating of the N^{th}-order objective function.

As an exemplary embodiment, the NTGK model may be built as an NTGK voltage model by applying the optimal parameters, and the NTGK voltage model may output the SOH of the battery as “SOH=xxx%.”

In accordance with another embodiment of the present disclosure, there is provided a battery state of health (SOH) model building system including a Newman, Tiedmann, Gu, and Kim (NTGK) server configured to build an NTGK voltage model from test data of a battery pack and output a model voltage from the NTGK voltage model, a vehicle customer relation management (VCRM) server configured to analyze actual vehicle driving/charging battery data of a battery mounted in a vehicle and output a measured voltage, and an optimization server configured to set an error between the model voltage and the measured voltage, apply a capacity and resistance of the battery, as optimization elements, to an objective function, derive optimal parameters for the capacity and the resistance in a process of minimizing the error using a gradient descent algorithm of machine learning for the objective function, and optimize the NTGK voltage model as the optimal parameters.

As an exemplary embodiment, the NTGK server may use an NTGK model to which the capacity and the resistance of the battery cell are applied as parameters.

As an exemplary embodiment, the actual vehicle driving/charging battery data may be provided to the VCRM server through a VCRM terminal installed in the vehicle.

As an exemplary embodiment, the NTGK voltage model may be applied to an SOH estimation terminal, and the SOH estimation terminal may display the SOH of the battery as “SOH=xxx%” through a display in a state of being mounted in the vehicle.

### BRIEF DESCRIPTION OF THE DRAWINGS

FIG. 1 is a flowchart illustrating a method of building a battery state of health (SOH) estimation model based on actual vehicle collection big data according to embodiments of the present disclosure.

FIG. 2 is a diagram illustrating an example of a configuration of a battery SOH model building system in which an SOH estimation terminal is built as a Newman, Tiedmann, Gu, and Kim (NTGK) voltage model according to embodiments of the present disclosure.

FIG. 3 is a conceptual diagram illustrating an NTGK model of a battery pack according to embodiments of the present disclosure.

FIG. 4 is a diagram illustrating an example of an operation of an optimization execution server performing parameter derivation optimization of the NTGK model based on actual vehicle collection big data according to embodiments of the present disclosure.

FIG. 5 is a diagram illustrating an example of a battery SOH estimation result through parameter optimization of the NTGK voltage model according to embodiments of the present disclosure.

### DETAILED DESCRIPTION OF ILLUSTRATIVE EMBODIMENTS

Exemplary embodiments of the present disclosure will be described below in more detail with reference to the accompanying drawings, and these embodiments are examples of the present disclosure and may be embodied in various other different forms by those skilled in the art to which the present disclosure pertains so that the present disclosure is not limited to these embodiments.

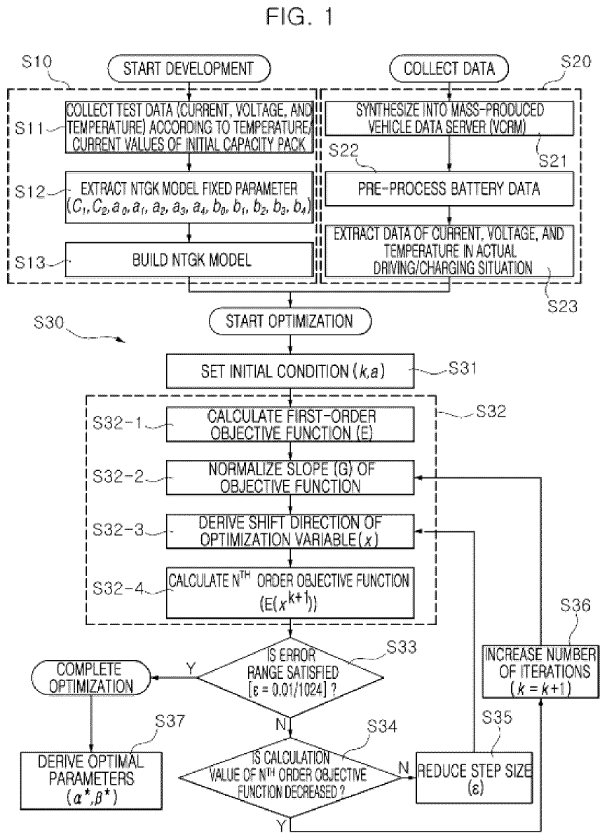

Referring to FIG. 1, a method of building a battery state of health (SOH) estimation model includes establishing a battery Newman, Tiedmann, Gu, and Kim (NTGK) model (S10) in which an NTGK voltage model is built using model fixed parameters extracted through battery test data, extracting battery big data (S20) in which actual vehicle parameters are extracted using actual vehicle driving/charging battery data as big data, and optimizing an NTGK model of the battery (S30) in which model optimal parameters are derived from the model fixed parameters and the actual vehicle parameters through optimization objective function processing to allow the NTGK voltage model to replace the fixed parameters as the optimal parameters.

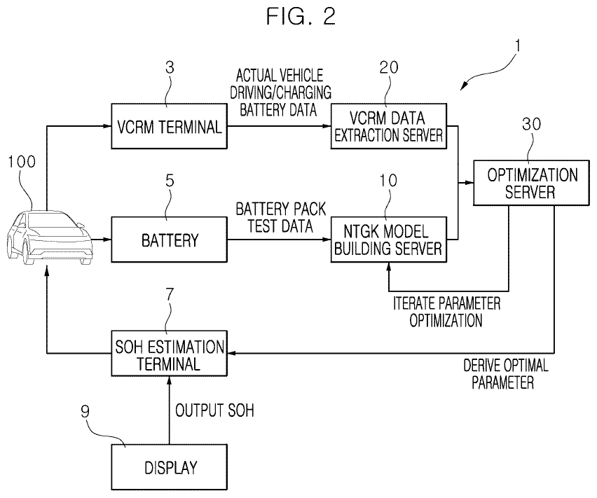

In this way, the method of building a battery SOH estimation model may apply, by an optimization server 30 (see FIG. 2), any one of an error of a model voltage V_{pack}, an error of a measured voltage V_{pack}, a battery capacity α, and battery resistance β as an objective function G and derive optimal parameters α* and β* of a battery 5 (see FIG. 2) mounted on the vehicle through error minimization processing.

Thus, the method of building a battery SOH estimation model is characterized as a method of building a battery SOH estimation model based on actual vehicle collection big data, in which: first, since a current capacity is extracted using driving data of an individual vehicle and an optimization algorithm, it is possible to derive an SOH of the individual vehicle reflecting a driver's characteristics; second, since a driving/charging profile of an actual vehicle is used, a durability test taking a long period of time is unnecessary in a vehicle development stage; third, since the SOH of the battery can be indirectly identified through parameter extraction of the voltage model, expandability through the voltage model is large; and fourth, advancement of the control algorithm reflecting the chemical characteristics of the battery pack, which change according to a change in SOH, is possible.

Referring to FIG. 2, a battery SOH model building system 1 includes an NTGK model building server 10 using the NTGK model, a vehicle customer relation management (VCRM) data extraction server 20 using VCRM, and the optimization server 30.

In particular, the NTGK model building server 10 outputs a model voltage V_{pack} from test data of a battery pack 5A, which is built using the NTGK model, the VCRM data extraction server 20 outputs a measured voltage V_{pack} from actual vehicle driving/charging battery data of the battery 5 mounted in a vehicle 100, and the optimization server 30 is connected to the NTGK model building server 10 and the VCRM data extraction server 20, receives the model voltage V_{pack} and the measured voltage V_{pack}, and applies a gradient descent algorithm of machine learning to an error minimization process with respect to a setting error.

For example, the NTGK model allows Y, which is an electrical conductivity characteristic obtained through a battery discharge test, and U, which is a voltage characteristic obtained through the battery discharge test, to obtain a 5^{th} approximation coefficient value of a function model with respect to a depth of discharge (DoD). In this case, the NTGK model is built as an NTGK voltage model through an NTGK model part 10A of the NTGK model building server 10.

For example, VCRM is a big data technology of VCRM data analysis algorithm of a server (i.e., the VCRM data extraction server 20) and collects VCRM information from an electronic control unit (ECU) inside the vehicle to transmit the VCRM information to a server in real time through wireless data communication so that data generated inside the vehicle may be analyzed and utilized in real time. In this case, the VCRM is implemented through a VCRM terminal 3 installed in the vehicle 100.

Here, the method of building a battery SOH estimation model based on actual vehicle collection big data of FIG. 1 will be described in detail with reference to FIGS. 2 to 5. In this case, control main bodies are the NTGK model building server 10, the VCRM data extraction server 20, and the optimization server 30, and a control target is the NTGK voltage model.

First, the NTGK model building server 10 performs the establishing of an NTGK model of battery (S10).

Referring to FIG. 2, the NTGK model building server 10 extracts a temperature C and SOC capacities a and b, as model fixed parameters, from a current, a voltage, and a temperature of test data according to temperature/current values of an initial capacity pack with respect to the battery pack 5A of the battery 5 used as a power source of the vehicle 100 and selects the NTGK model using model variable parameters including a capacity α and resistance β of the battery 5 as parameters among models, each deriving a voltage output with respect to a current input, thereby building an NTGK voltage model capable of performing voltage estimation. In this case, a resistance value, which is a parameter of the NTGK model, uses an inverse number of electrical conductivity Y. This is due to the fact that, since the resistance value has a characteristic changing nonlinearly according to an SOC inside the battery, an internal resistance value 1/Y and polarization U have a direct relationship with a capacity Q.

Therefore, the establishing of the NTGK model of the battery (S10) includes collecting test data (a current, a voltage, and a temperature) according to the temperature/current values of the initial capacity pack (S11), extracting an NTGK model fixed parameter (S12), and building an NTGK model (S13).

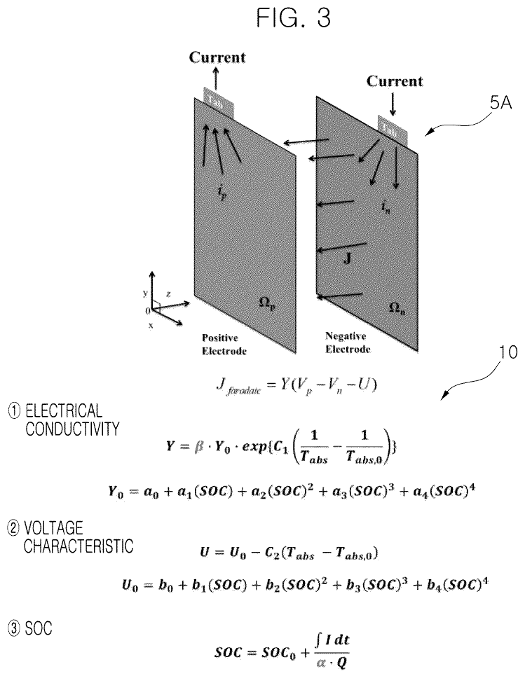

Referring to FIG. 3, a concept of the NTGK model is on the basis of “J=J_{faradaic}+J_{nonfaradaic}” of an electrochemical reaction generated when a current is input to the battery pack 5A with a negative electrode and a positive electrode.

As an example, “J=J_{faradaic}+J_{nonfaradaic}” is simplified to “J=J_{faradaic}” by omitting “J_{nonfaradaic},” and the NTGK voltage model in Table 1 is established from “J_{faradaic}=Y(Vp−Vn−U).” In this case, “Y” denotes electrical conductivity, “Vp,Vn” denotes a voltage, and “U” denotes a voltage characteristic.

In Table 1, the NTGK voltage model is exemplified such that inputs are set as a current I and temperatures T_{abs} and T_{abs,0}, an output is set as a pack voltage V_{pack}, set initial values are an SOC₀ of the battery and an internal capacity Q of the battery, model fixed parameters are set as battery temperature related parameters C₁ and C₂ and SOC related parameters a₀, a₁, a₂, a₃, a₄, b₀, b₁, b₂, b₃, and b₄, and model variable parameters are set as the capacity α and the resistance β of the battery.

In particular, the model fixed parameters C₁, C₂, a₀, a₁, a₂, a₃, a₄, b₀, b₁, b₂, b₃, and b₄ reflect the fact that battery resistance and polarization have non-linear characteristic curves according to the SOC and the temperature by applying the SOC related parameters a₀, a₁, a₂, a₃, and a₄ to an electrical conductivity equation Y, applying the temperature related parameters C₁ and C₂ and the SOC related parameters b₀, b₁, b₂, b₃, and b₄ to a voltage equation U, performing a reference performance test (RPT) for each temperature and each current value through an initial state of the battery pack 5A, and extracting the model fixed parameters from the current/voltage/temperature collected through regression.

In addition, the model variable parameters α and β indicate a degree of degradation in resistance and capacity values representing the SOH of the battery so that the NTGK model may be applied to the SOH estimation.

Therefore, in the collecting of the test data (S11), the RPT is performed for each temperature and each current value through the initial state of the battery pack 5A, and then the current/voltage/temperature are collected through regression, and in the extracting of the fixed parameter (S12), the temperature/SOC related parameters C₁, C₂, a₀, a₁, a₂, a₃, a₄, b₀, b₁, b₂, b₃, and b₄ are extracted, as the model fixed parameters, from the test data, and in the building of the NTGK model (S13), the NTGK voltage model is developed so that a voltage V is estimated as an output from the electrical conductivity equation Y to which the SOC related parameters a₀, a₁, a₂, a₃, and a₄ are applied and the voltage equation U to which the temperature related parameters C₁ and C₂ and the SOC related parameters b₀, b₁, b₂, b₃, and b₄ are applied.

Subsequently, in the extracting of the battery big data (S20), the VCRM data extraction server 20 extracts pieces of data of a current I, a temperature T, and a voltage V_{pack} as actual vehicle parameters by utilizing the actual vehicle driving/charging battery data as big data.

To this end, the extracting of the battery big data (S20) includes synthesizing the pieces of data into a mass-produced vehicle data server (S21), pre-processing battery data (S22), and extracting pieces of data of a current I, a temperature T, and a voltage V_{pack} in an actual driving/charging situation (S23). In this case, the mass-produced vehicle data server is the VCRM data extraction server 20, and the pre-processed battery data is the actual vehicle driving/charging battery data transmitted from the VCRM terminal 3.

Referring to FIG. 2, the VCRM data extraction server 20 extracts the current I, the temperature T, and the voltage V_{pack}, as actual vehicle parameters, from the big data using the actual vehicle driving/charging battery data of the battery 5 installed and operated in the vehicle 100 through the VCRM terminal 3 installed in the vehicle 100 using an artificial intelligence technique.

In particular, for an algorithm of the pre-processing of the battery data (S22), the VCRM data extraction server 20: (1) as a data application unit determines a start-up on-off section as one data set, prevents time-series characteristics from being broken on the basis of the big data, (2) minimizes a polarization effect using a data set in which a rest period is present for one hour or more after a period of a start-up off in a previous data set before a start-up on, (3) uses only information on the voltage/current/temperature, which is data obtained through actual measurement, (4) determines an initial SOC value through a measured voltage value, and (5) uses an inherent open circuit voltage (OCV)-SOC characteristic curve of the battery.

Finally, the optimization server 30 performs the optimizing of the NTGK model of the battery (S30). In this way, optimal parameters are derived from the model fixed parameters and the actual vehicle parameters through optimization objective function processing to allow the NTGK voltage model to convert the fixed parameters into the optimal parameters.

Referring to FIG. 2, the optimization server 30 sets optimization elements α (capacity) and β (resistance) as battery SOH estimation model parameters, calculates and sets an objective function E as an error between an actually measured voltage value and a voltage value derived by the NTGK voltage model, and implements optimization of a gradient descent algorithm G which is a machine learning technique to meet an error range, thereby deriving the optimization elements α and β as optimal parameters α* and β*. In this case, the optimal parameters β* and β*, which are the derived result values of the optimization algorithm, are SOH parameter values at which the error between the actually measured voltage value and a voltage simulation value of the NTGK model becomes the smallest.

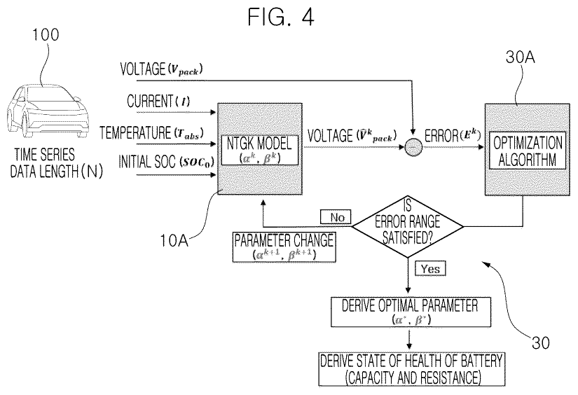

Referring to FIG. 4, the optimization algorithm performed by the optimization server 30 through an optimization logic part 30A sets optimization elements α and β reducing an error region between a model voltage and an actual vehicle voltage, finds optimal parameters representing the SOH of the battery by reducing an error using the objective function and a machine learning technique of a gradient descent method, and derives the optimization elements α and β as optimal parameters α* and β*.

In particular, the model voltage refers to the voltage V_{pack} provided by a NTGK model part 10A of the NTGK model building server 10 as an output of the NTGK voltage model, the actual vehicle voltage refers to the voltage V_{pack} which is the actual battery measurement data provided by the VCRM data extraction server 20 as the actual vehicle parameter, and the error refers to an error between an actual voltage value of an aging battery (i.e., a vehicle-mounted battery) and a voltage value which is a model result value.

Specifically, the optimizing of the NTGK model of the battery (S30) includes setting an initial condition (S31), calculating an nt h order objective function (S32), confirming whether an error range is satisfied (S33), repeating the procedure (S34 to S36), and deriving optimal parameters (S37).

Herein, k is defined as the number of times optimization is performed, E is defined as the objective function, Eₖ is defined as a k^{th} optimization objective function of the optimization process, V_{pack}k is defined as the actual battery voltage (measured data), V\hat{ }_{pack} is defined as a k^{th} predicted battery voltage (model data) of the optimization process, N is defined as a total time step, G is defined as a slope of the objective function, and c is defined as the error.

For example, in the setting of the initial condition (S31), an initial value for optimization processing to reduce an error between the model voltage and the measured voltage is set as follows.

Initial setting condition: k=0 & z=0.01

As an example, the calculating of the objective function with an n^{th} order (S32) is an n^{th} order iteration procedure to reach an optimization process and includes calculating a first-order objective function (S32-1), normalizing a slope of the objective function (S32-2), deriving a shift direction of the optimization variable (S32-3), and calculating an N^{th}-order objective function (S32-4).

To this end, in the calculating of the first-order objective function (S32-1), an optimization variable x is processed using the objective function E.

$$Optimization variable ( x ) : {x}^{k} = [ {α}^{k} , {β}^{k} ]$$

$$Objective function ( E ) : \text{?}$$

$$\text{?} \text{indicates text missing or illegible when filed}$$

Thus, the objective function is calculated to reduce a voltage value error between an actual voltage value of the aging battery and a voltage value obtained through a test, which is the model result value, using the optimization elements α and β for the model parameters of the NTGK voltage model, and this calculation is repeated from one time step to the total time step.

In addition, in the normalizing of the slope of the objective function (S32-2), a slope G is calculated using a gradient descent method, and in the deriving of the shift direction of the optimization variable (S32-3), the optimization elements α and β are shifted in a direction of optimization shift, and in the calculating of the n^{th}-order objective function (S32-4), an optimization variable x^{k+1} to which an optimization shift value is applied is processed using an objective function E^{k+1}.

$$Gradient descent method : \text{?}$$

$$Optimization shift value : \text{?}$$

$$\text{?} \text{indicates text missing or illegible when filed}$$

Thus, the gradient descent method is performed with a machine learning technique for finding an optimal parameter representing an SOH, the machine learning technique derives a shift direction for optimization by normalizing the slope G using the slope G of the objective function, and the model parameter (x^{k}=[α^{k},β^{k}]) is shifted in the direction of reducing the objective function in each iteration for optimization.

As a result, the optimization elements α and β are derived as a first-order calculation value of the objective function E(x⁰) and an N^{th}-order calculation value of the objective function E(x^{k+1}).

For example, in the confirming of whether the error range is satisfied (S33), a tolerance value is applied.

Tolerance value: ε=0.01/1024 and z=0.01

As a result, as shown in FIG. 4, when “ε=0.01/1024” is satisfied, the procedure is switched to an operation of deriving an optimal parameter (S37) so that the NTGK voltage model of the NTGK model building server 10 replaces the existing optimization elements α and β with the optimal parameters α* and β*, which are the values derived from the optimization algorithm, and the optimal parameters α* (capacity) and β* (resistance) represent SOH parameter values at which an error between the actual measured voltage value and the voltage simulation value of the NTGK model is the smallest.

Otherwise, as shown in FIG. 4, when “ε=0.01/1024” is not satisfied, the procedure for finding the optimal parameters α* and β* using the optimization elements α and β as change parameters α* and β* is repeated.

Therefore, the repeating of the procedure (S34 to S36) includes confirming a decrease in a calculation value of the N^{th}-order objective function (S34), reducing a step size (S35), increasing the number of iterations (S36), and deriving optimal parameters (S37).

For example, the confirming of the decrease in the calculation value of the N^{th}-order objective function (S34) is performed through an objective function reduction condition.

Objective function reduction condition: E(x^{k+1})<E(x⁰)

As a result, when the N^{th}-order calculation value E(x^{k+1}) of the objective function for the optimization elements α and β is not smaller than the first-order calculation value E(x⁰) of the objective function, the procedure enters the reducing of the step size (S35).

For example, the reducing of the step size (S35) is performed by resetting an error satisfaction value, and then the procedure returns to the deriving of the shift direction of the optimization variable (S32-3) to perform subsequent operations.

Error satisfaction value resetting: ε=ε/2

As described above, in the reducing of the step size (S35), the objective function value E(x^{k+1}) of a current iteration being greater than the objective function value E(x⁰) of a previous iteration in the optimization process passes through an optimal point so that a previous step size is reduced ½ and the optimization element is shifted in a direction of the optimal point again.

On the other hand, when the N^{th}-order calculation value E(x^{k+1}) of the objective function for the optimization elements α and β is smaller than the first-order calculation value E(x⁰) of the objective function, the procedure enters the increasing of the number of iterations (S36).

Increasing of the number of iterations: k=k+1

For example, the increasing of the number of iterations (S36) is performed by increasing the number of iterations, and then the procedure returns to the normalizing of the slope of the objective function (S32-2) to perform subsequent operations.

In this way, in the increasing of the number of iterations (S36), the model parameter elements are shifted in the direction of reducing the objective function in a corresponding iteration in the optimization process (x^{k+1}=[α^{k+1},β^{k+1}]) (see FIG. 4), and then the iteration continues by increasing the number of times of calculation by one (k=k+1).

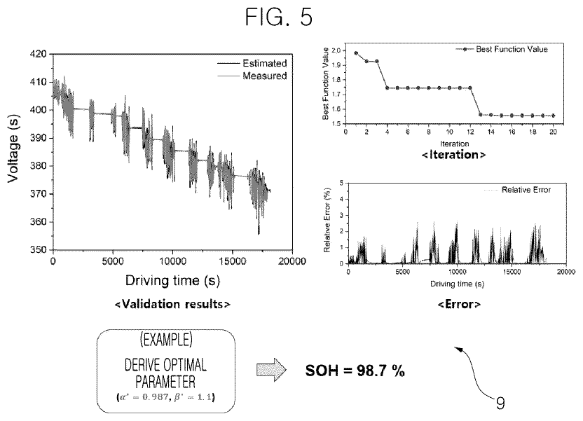

Meanwhile, referring to FIG. 5, it can be seen that the NTGK voltage model replaces the optimization elements α and β with the optimal parameters α* and β* through parameter optimization so that estimation results of the SOH of the battery are exemplified from a validation results image graph, an iteration image graph, and an error image graph.

For example, when an SOH estimation result through the parameter optimization of the voltage estimation model (NTGK) is α*=0.987 and β*=1.1, it was experimentally proved that the SOH of the battery 5 mounted in the vehicle 100 was SOH=98.7%.

Referring to FIG. 2, the battery SOH model building system 1 builds an SOH estimation terminal 7 using the NTGK voltage model to which the optimal parameters α* and β* are applied, and the SOH estimation terminal 7 is installed in the vehicle 100. Thus, during vehicle traveling, an SOH of the battery 5 is estimated and the estimated result is displayed as internal resistance β* and a capacity α* so that a current SOH of the battery 5 may be confirmed.

To this end, the SOH estimation terminal 7 includes a display 9, and the display 9 informs the outside of a graph image including information of “SOH=xxx%” (see FIG. 5).

As described above, the method of building a battery SOH estimation model based on actual vehicle collection big data implemented in the battery SOH model building system 1 according to the present embodiment builds, by the NTGK model building server 10, an NTGK voltage model using the test data acquired from the battery pack 5A to output the model voltage, outputs, by the VCRM data extraction server 20, a measured voltage from the actual vehicle driving/charging battery data of the battery 5 analyzed by artificial intelligence, minimizes, by the optimization server 30, the error setting values for the model voltage and the measured voltage using a gradient descent algorithm of machine learning for the objective function, derives and applies the optimal parameters α* and β* to the NTGK voltage model, and outputs the SOH of the battery 5 as “SOH=xxx%.”

Therefore, according to the method of building a battery SOH estimation model based on actual vehicle collection big data, by using the actual vehicle driving/charging battery data collected from mass-produced vehicles as big data, estimation of the SOH of the battery with high accuracy in real time in consideration of the driver's driving pattern, effective classification and learning of accumulated actual driving history data according to operating conditions, and advancement of the control algorithm reflecting chemical characteristics of the battery pack, which change according to a change in SOH condition, are possible.

A method of building a state of health (SOH) estimation model of a battery based on actual vehicle collection big data implemented in a battery SOH model building system of embodiments of the present disclosure implements operations and effects as follows.

First, advancement of a control algorithm reflecting chemical characteristics of a battery pack, which change according to a change in SOH condition, is possible. Second, an algorithm which accurately estimates a capacity and resistance, which are current SOH conditions of a battery, by utilizing actual driving/charging big data collected from mass-produced vehicles can be implemented. Third, a voltage estimation model is built by optimizing parameters of Newman, Tiedmann, Gu, and Kim (NTGK) using actual big data so that effective classification and learning of actual driving history data and advancement of the control algorithm reflecting chemical characteristics of the battery pack, which change according to a change in SOH condition, can be implemented. Fourth, driving data and an optimization algorithm of an individual vehicle are used to estimate the SOH (capacity and resistance) of the battery on the basis of the voltage estimation model so that an SOH of the individual vehicle to which a driver's characteristic is reflected can be derived by extracting a current capacity of the battery. Fifth, since a driving/charging profile of an actual vehicle is used, a durability test taking a long period of time is unnecessary in a vehicle development stage and, particularly, it is easy to verify actual vehicle measurement data and battery system assembly (BSA) units so that the characteristics of individual vehicles can be easily reflected to the SOH of the battery.

While embodiments of the present disclosure have been described with reference to the accompanying drawings, it will be apparent to those skilled in the art that various changes and modifications can be made without departing from the spirit and scope of the present disclosure without being limited to the exemplary embodiments disclosed herein. Accordingly, it should be noted that such alternations or modifications fall within the claims of the present disclosure, and the scope of the present disclosure should be construed on the basis of the appended claims.

What is claimed is:

1. A method of building a battery state of health (SOH) estimation model, the method comprising:
applying, by an optimization server, an error of a model voltage, an error of a measured voltage, a capacity, or a resistance of a battery mounted in a vehicle as an objective function; and
performing error minimization processing to derive optimal parameters of the battery.

2. The method of claim 1, wherein:
the model voltage is output from test data of a battery pack, which is built using a Newman, Tiedmann, Gu, and Kim (NTGK) model by an NTGK server;
the measured voltage is output from actual vehicle driving/charging battery data of the battery mounted in the vehicle by a vehicle customer relation management (VCRM) server; and
the error minimization processing is performed using a gradient descent algorithm of machine learning by the optimization server.

3. The method of claim 2, wherein building the NTGK model by the NTGK server comprises:
collecting the test data in an initial capacity state in which the battery pack is not charged and discharged;
extracting parameters related to a temperature and the resistance from the test data as model fixed parameters; and
performing NTGK processing on the model fixed parameters and building the NTGK model in which the model voltage is an output value.

4. The method of claim 3, wherein the test data comprises a current, a voltage, and the temperature according to a temperature value and a current value.

5. The method of claim 2, further comprising extracting battery big data of the battery from the VCRM server, wherein extracting the battery big data comprises:
synthesizing, by the VCRM server, the actual vehicle driving/charging battery data of the battery transmitted from a VCRM terminal mounted in the vehicle;
performing data pre-processing using the actual vehicle driving/charging battery data as the battery big data through artificial intelligence; and
extracting actual vehicle parameters having the measured voltage as an output value from the data pre-processing as a current, a temperature, and a voltage of the battery.

6. The method of claim 5, wherein performing the data pre-processing comprises:
applying a data unit which uses start-up on/off periods of the vehicle as one data set;
using a data set of a rest period after a start-up off period of a previous data set before a start-up on period;
using actual measurement information on the current, and the temperature, and the voltage;
applying two or more of determined initial state of charge (SOC) values of the battery based on the measured voltage as a setting condition; and
analyzing and classifying the actual vehicle driving/charging battery data using the setting condition.

7. The method of claim 6, wherein the rest period is set to one hour after the start-up off period.

8. The method of claim 2, further comprising optimizing, by the optimization server, the NTGK model of the battery, wherein optimizing the NTGK model comprises:
setting an initial condition for reducing the error;
calculating an N^{th}-order objective function by applying the capacity and the resistance as optimization elements and processing the objective function using the optimization elements by the gradient descent algorithm;
determining whether a tolerance value is satisfied;
in response to a determination that the tolerance value is not satisfied, performing calculating the N^{th}-order objective function again, repeating the optimizing, and finding the optimal parameters for the optimization elements; and
in response to a determination that the tolerance value is satisfied, deriving the optimization elements as the optimal parameters.

9. The method of claim 8, wherein calculating the N^{th}-order objective function comprises:
setting a calculation result of the objective function as a first-order calculation value of the objective function;
normalizing a slope of the objective function using the gradient descent algorithm;
applying the slope of the objective function to the tolerance value and deriving a shift direction of the optimization elements; and
setting the calculation result of the objective function as an N^{th}-order calculation value of the objective function in the shift direction of the optimization elements.

10. The method of claim 9, wherein repeating the optimizing comprises:
comparing the N^{th}-order calculation value of the objective function with the first-order calculation value of the objective function;
in response to the N^{th}-order calculation value of the objective function being greater than the first-order calculation value of the objective function, reducing a step size for changing the tolerance value; and
in response to the N^{th}-order calculation value of the objective function being smaller than the first-order calculation value of the objective function, increasing a number of repetitions of a total type step.

11. The method of claim 10, wherein reducing the step size comprises setting to ½ compared to a previous step size.

12. The method of claim 11, further comprising, after reducing the step size, returning to deriving the shift direction of the optimization elements during calculating the N^{th}-order objective function by applying the slope of the objective function to the tolerance value.

13. The method of claim 10, wherein increasing the number of repetitions comprises returning to normalizing the slope of the objective function using the gradient descent algorithm during calculating the N^{th}-order objective function.

14. The method of claim 2, wherein:
the NTGK model is built as an NTGK voltage model by applying the optimal parameters; and
the NTGK voltage model outputs the SOH of the battery as “SOH=xxx%.”

15. A battery state of health (SOH) model building system, the system comprising:
a Newman, Tiedmann, Gu, and Kim (NTGK) server configured to build an NTGK voltage model from test data of a battery pack and output a model voltage from the NTGK voltage model;
a vehicle customer relation management (VCRM) server configured to analyze actual vehicle driving/charging battery data of a battery mounted in a vehicle and output a measured voltage; and
an optimization server configured to set an error between the model voltage and the measured voltage, apply a capacity and a resistance of the battery, as optimization elements, to an objective function, derive optimal parameters for the capacity and the resistance in a process of minimizing the error using a gradient descent algorithm of machine learning for the objective function, and optimize the NTGK voltage model as the optimal parameters.

16. The system of claim 15, wherein the NTGK server is configured to use an NTGK model to which the capacity and the resistance of the battery are applied as parameters.

17. The system of claim 15, further comprising a VCRM terminal in the vehicle, wherein the VCRM terminal is configured to provide the actual vehicle driving/charging battery data to the VCRM server.

18. The system of claim 15, wherein:
the NTGK voltage model is configured to be applied to an SOH estimation terminal; and
the SOH estimation terminal is mounted in the vehicle and is configured to output an SOH of the battery.

19. The system of claim 18, wherein:
the SOH estimation terminal is connected to a display; and
the display is configured to display the SOH as “SOH=xxx%.”
